(19) United States
(12) Patent Application Publication
(10) Pub. No.: US 2008/0117597 A1
(43) Pub. Date: May 22, 2008

(54) LIGHT EMITTING DIODE MODULE HAVING A THERMAL MANAGEMENT ELEMENT

(75) Inventors: ZHI-YONG ZHOU, Shenzhen (CN); CHENG-TIEN LAI, Tu-Cheng (TW); YI-SAN LIU, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/561,344

(22) Filed: Nov. 17, 2006

(51) Int. Cl. H05K 7/20

(52) U.S. Cl. 361/700

(57) ABSTRACT

An LED module includes an LED, a heat spreader contacting the LED, a heat-dissipating unit remote from the LED and a heat transfer member. The heat transfer member thermally connects the heat spreader and the heat-dissipating unit and transfers heat from the heat spreader to the heat-dissipating unit.

### BACKGROUND OF THE INVENTION

1. Field of the Invention

The present invention relates to a light emitting diode module, more particularly to a light emitting diode module having a thermal management element for removing heat from the light emitting diode.

2. Description of Related Art

A light emitting diode (LED) is a device for transforming electricity into light. When a current is made to flow to a junction comprising two different semiconductors, electrons and holes combine to generate light. The LEDs are small, inexpensive, low power, etc., and has an almost eternal lifetime under specific conditions, so more and more LED modules with different capabilities are being developed.

Generally, LED modules for use in a display or an illumination devices require many LEDs, and most of the LEDs are used at the same time, which results in a quick rise in temperature of the LED modules. While, the LEDs are sensitive to temperature and may be permanently damaged by excessive temperature. High temperature performance of LEDs is an adverse aspect of LED technology that has not been satisfactorily resolved.

Since most LED modules do not have thermal management element with good heat dissipating efficiencies, operation of the general LED modules are often erratic and unstable because of the rapid build up of heat.

What is needed, therefore, is an LED module having a thermal management element having a sufficient heat removal capability.

### SUMMARY OF THE INVENTION

An LED module having a thermal management element is provided. The LED module includes an LED, a heat spreader contacting the LED, a heat-dissipating unit remote from the LED and a heat transfer member. The heat transfer member thermally connects the heat spreader and the heat-dissipating unit and transfers heat from the heat spreader to the heat-dissipating unit. The heat spreader and the heat-dissipating unit each have a large heat-dissipating surface in comparison with the LED, whereby the heat generated by the LED can be quickly dissipated by the heat spreader and the heat-dissipating unit. The heat transfer member transfers the heat on the heat spreader to the heat-dissipating unit which can be located at a clear location remote from the LED and can have a large heat-dissipating surface available to facilitate heat dissipation.

Other advantages and novel features will become more apparent from the following detailed description of preferred embodiments when taken in conjunction with the accompanying drawings, in which:

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an assembled schematic view of an LED module having a thermal management element in accordance with a first embodiment of the present invention;

FIG. 2 is an assembled view of a heat spreader and a heat pipe of the thermal management element of FIG. 1;

FIG. 3 is an assembled view of an LED module having a thermal management element in accordance with a second embodiment of the present invention;

FIG. 4 is an assembled view of a heat spreader and a heat pipe of a thermal management element for an LED module in accordance with a third embodiment of the present invention;

FIG. 5 is an assembled view of an LED module having a thermal management element in accordance with a fourth embodiment of the present invention;

FIG. 6 is an assembled view of an LED module having a thermal management element in accordance with a fifth embodiment of the present invention;

FIG. 7 is an assembled view of an LED module having a thermal management element in accordance with a sixth embodiment of the present invention;

FIG. 8 is an assembled view of an LED module having a thermal management element in accordance with a seventh embodiment of the present invention;

FIG. 9 is an assembled view of an LED module having a thermal management element in accordance with an eighth embodiment of the present invention;

FIG. 10 is an assembled view of an LED module having a thermal management element in accordance with a ninth embodiment of the present invention; and

FIG. 11 is an assembled view of an LED module having a thermal management element in accordance with a tenth embodiment of the present invention.

### DETAILED DESCRIPTION OF THE INVENTION

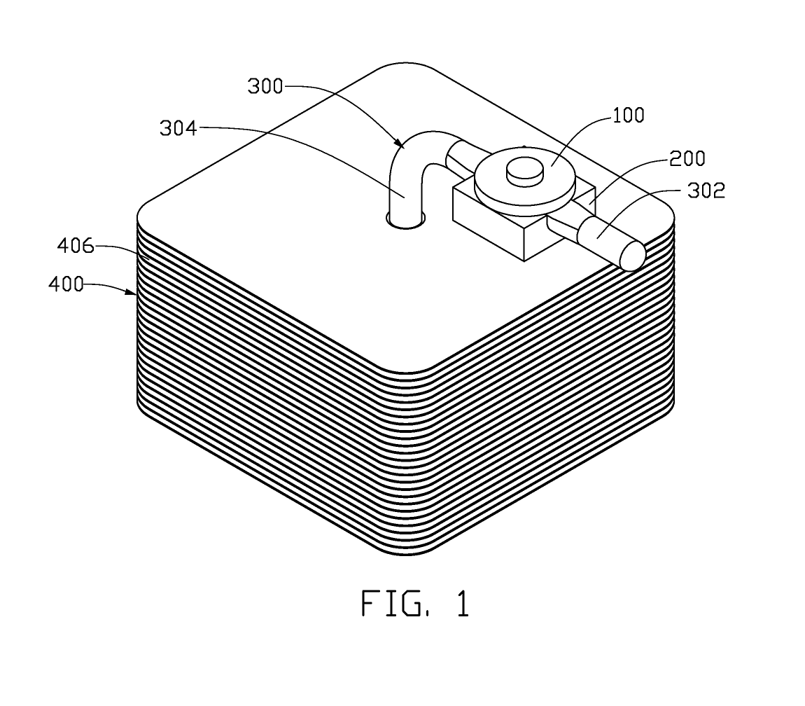

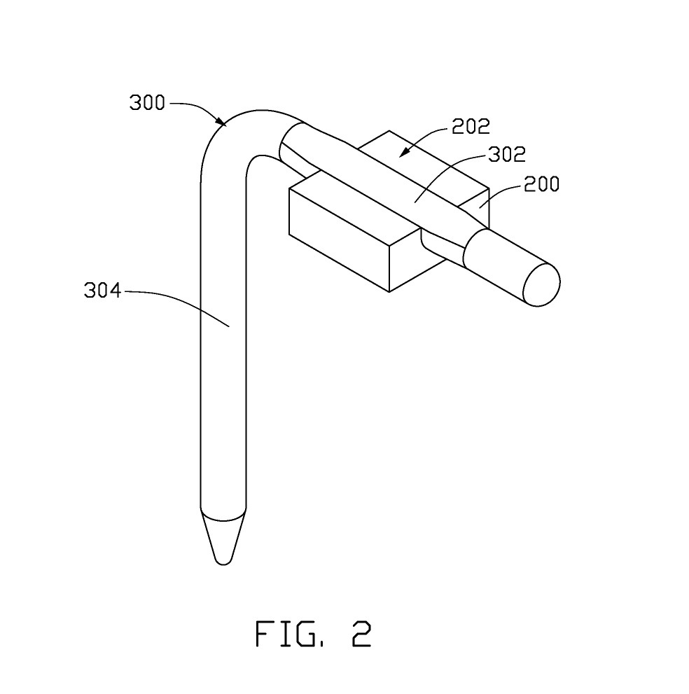

Referring to FIGS. 1 and 2, an LED module in accordance with a first embodiment of the present invention comprises an LED 100, a heat spreader 200, a heat-transfer member such as a heat pipe 300, and a heat dissipating unit 400. The heat pipe 300 has an evaporating section 302 engaged in the heat spreader 200, and a condensing section 304 perpendicular to the evaporating section 302 and inserted through the heat-dissipating unit 400. The heat-dissipating unit 400 comprises a plurality of metallic fins 406. The fins 406 are parallel to and separate from each other. A through hole (not labeled) is defined in the heat dissipating unit 400, transversely extending though all of the fins 406. The heat spreader 200 can be made of aluminum or copper material. The heat pipe 300 is inserted into the through hole of the heat dissipating unit 400 and thermally engaged with the metallic fins 406 by soldering. Furthermore, the heat pipe 300 can be engaged with the heat spreader 200 by soldering.

Since the LED 100 inherently has a too small surface available to sufficiently transfer heat thereof, a heat transfer member has a great heat-transfer capability is thus chosen to transfer the heat to a wide space to be dissipated out. The heat pipe 300 is a preferred member to quickly transfer heat from the LED 100 to the heat-dissipating unit 400 which can be arranged at a clear location remote from the LED 100 and can have a large heat-dissipating surface available to facilitate heat dissipation.

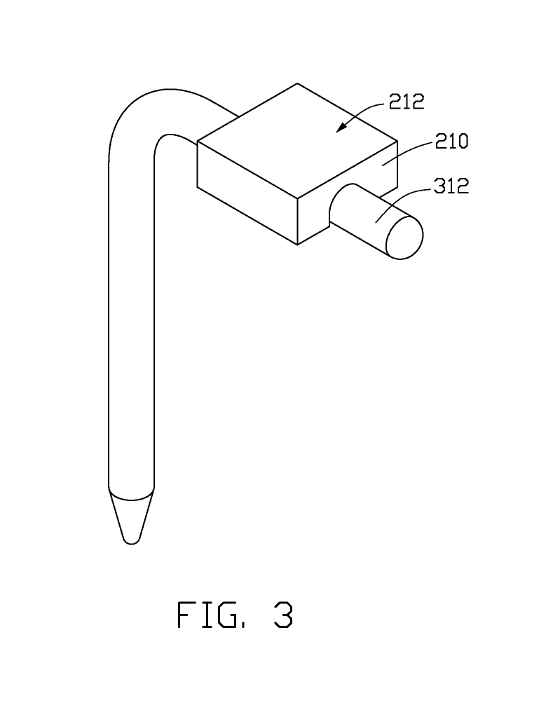

In the first embodiment, the evaporating section 302 of the heat pipe 300 is flattened at a side thereof, and incorporates the heat spreader 200 to commonly define a planar heat-receiving surface 202 so that both of the evaporating section 302 and the heat spreader 200 contact the LED 100. That is, the heat pipe 300 directly contacts the LED 100. However, the physical relationship between the evaporating section 302, the heat spreader 200 and the LED 100 is not limited as that in the first embodiment. For instance, in a second embodiment as shown in FIG. 3, the heat spreader 210 defines a planar surface 212 for contacting an LED. The evaporating section 312 of the heat pipe 310 is designed to be separated from the LED by the heat spreader 210. That is, the heat pipe 300 does not directly contact the LED. The heat pipe 310 absorbs heat from the heat spreader 210.

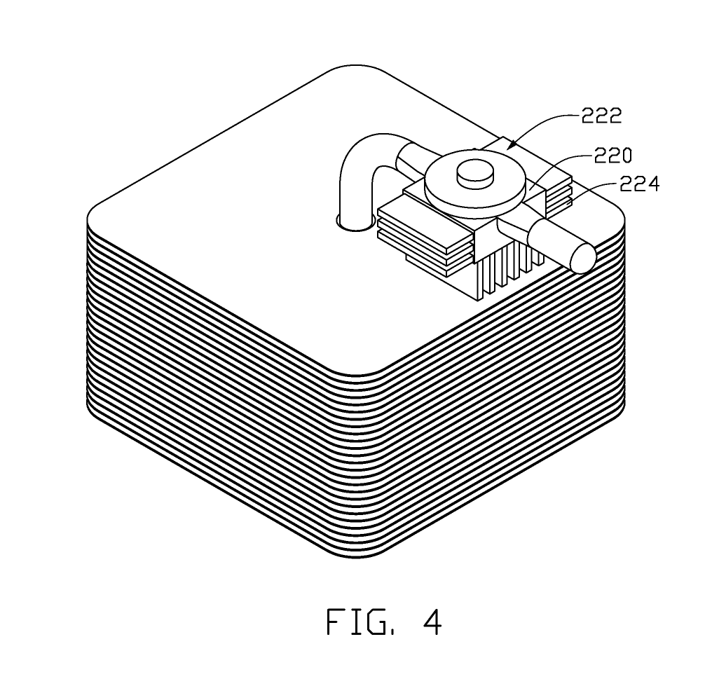

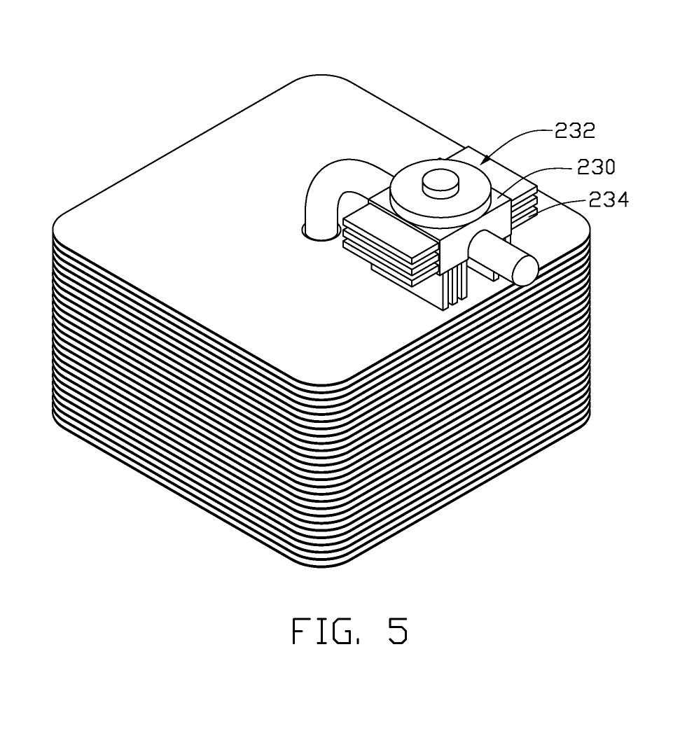

In the first and second embodiments, the heat spreader 200/210 is a plate-like bare metallic mass. However, in third and fourth embodiments as shown in FIG. 4 and FIG. 5, a plurality of metallic flakes 224/234 are extended outwardly from three side surfaces different from a heat-receiving surface 222/232 of a heat spreader 220/230 to enhance the thermal management efficiency of LED modules. The flakes 224/234 are integrally formed at or soldered to the heat spreader 220/230, alternatively.

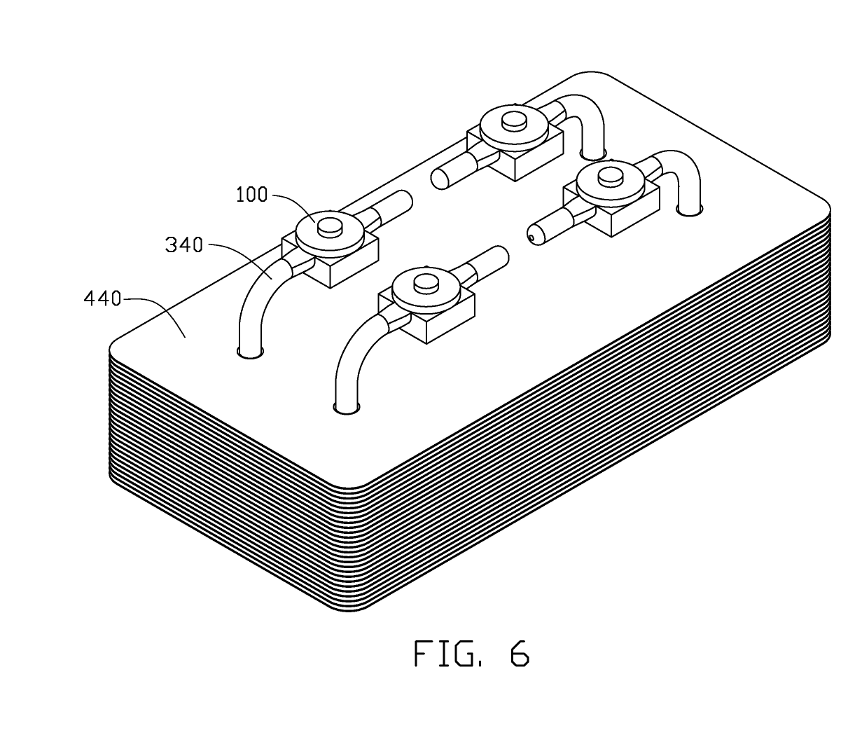

FIG. 6 shows an LED module in accordance with a fifth embodiment of the present invention. The main difference between this embodiment and the first embodiment is that four heat pipes 340 identical to the heat pipe 300 in the first embodiment are inserted into a heat-dissipating unit 440, and respectively employed to absorb heat from four individual LEDs 100.

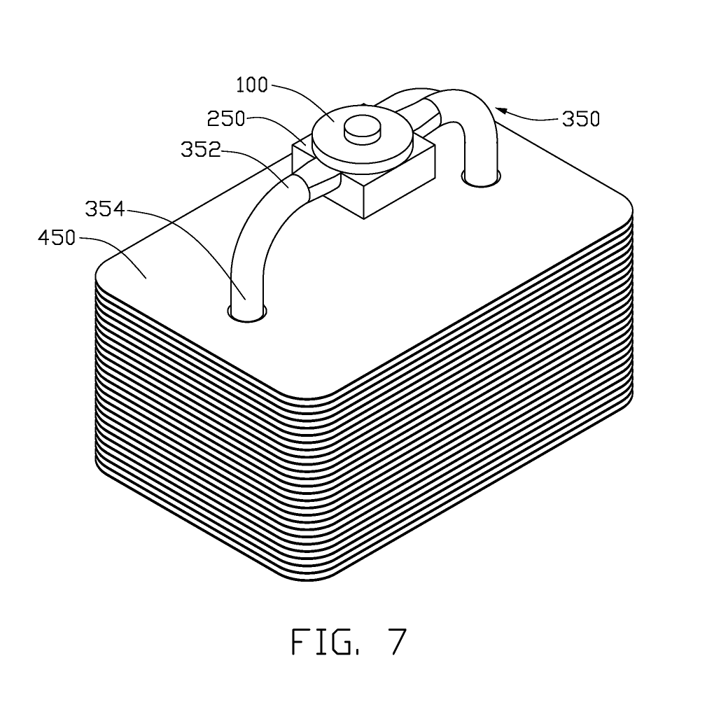

FIG. 7 is a sixth embodiment of an LED module. In this embodiment, a U-shaped heat pipe 350 is employed in comparison with the first embodiment. The heat pipe 350 comprises an evaporating section 352 engaged in the heat spreader 250 and two condensing sections 354 extending from opposite ends of the evaporating section 352. Both of the condensing sections 354 are inserted through the heat-dissipating unit 450.

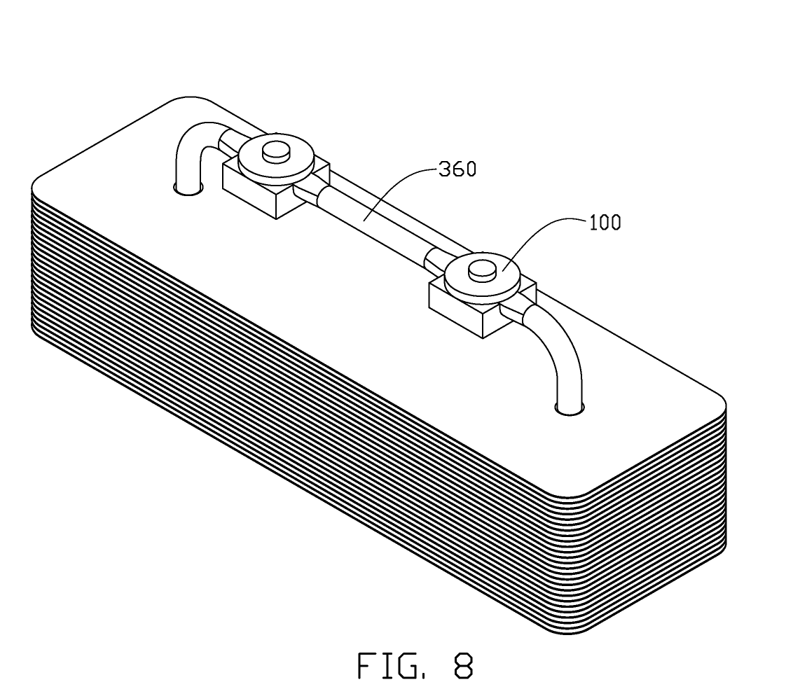

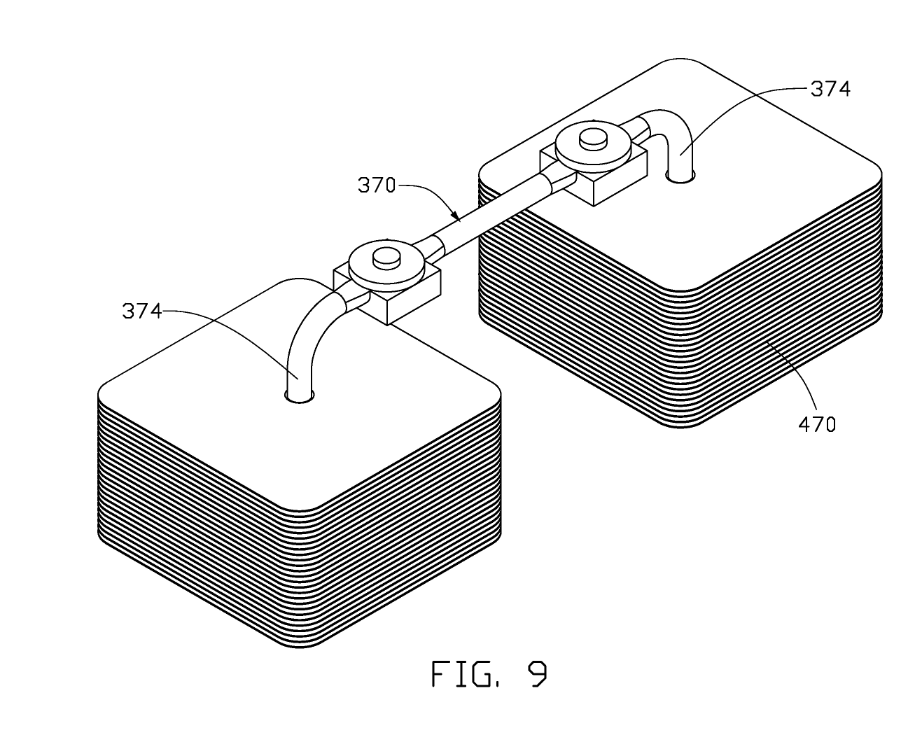

FIG. 8 shows an LED module similar to the LED module of FIG. 7, but the heat pipe 360 is engaged with two separate LEDs 100. FIG. 9 is similar to FIG. 8, but condensing sections 374 of the heat pipe 370 are inserted into two separate heat-dissipating units 470.

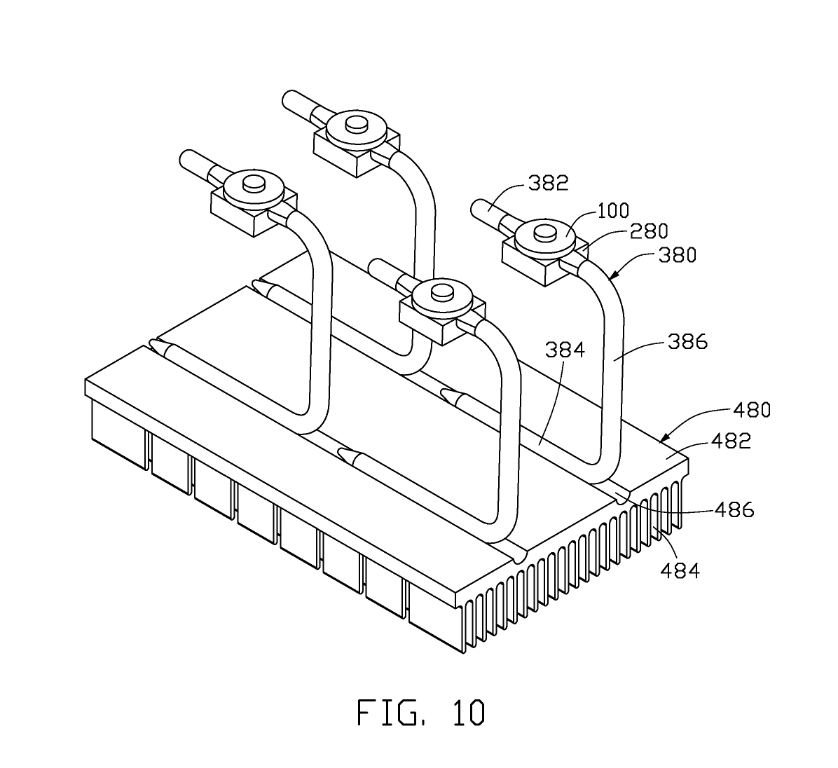

FIG. 10 shows a ninth embodiment of an LED module. The LED module comprises four LEDs 100, four heat spreaders 280, four U-shaped heat pipes 380 and a heat-dissipating unit 480. Each heat pipe 380 comprises an evaporating section 382, a condensing section 384 and a connecting section 386 connecting the evaporating section 382 and the condensing section 384. Each evaporating section 382 is engaged with a heat spreader 280 and an LED 100 in a same manner as that in the first embodiment. The heat-dissipating unit 480 comprises a base 482 and a plurality of fins 484 extending perpendicularly from the base 482 toward a direction away from the LEDs 100. Two straight grooves 486 are defined in the base 482. The grooves 486 and the fins 484 are located at opposite sides of the base 482. The condensing sections 384 are received in the grooves 486 by soldering. On the whole, all of the LEDs 100, the heat spreaders 280 and the heat pipes 380 are located at a first side of the base 482, while all of the fins 484 are located at a second side of the base 282 which is opposite to the first side.

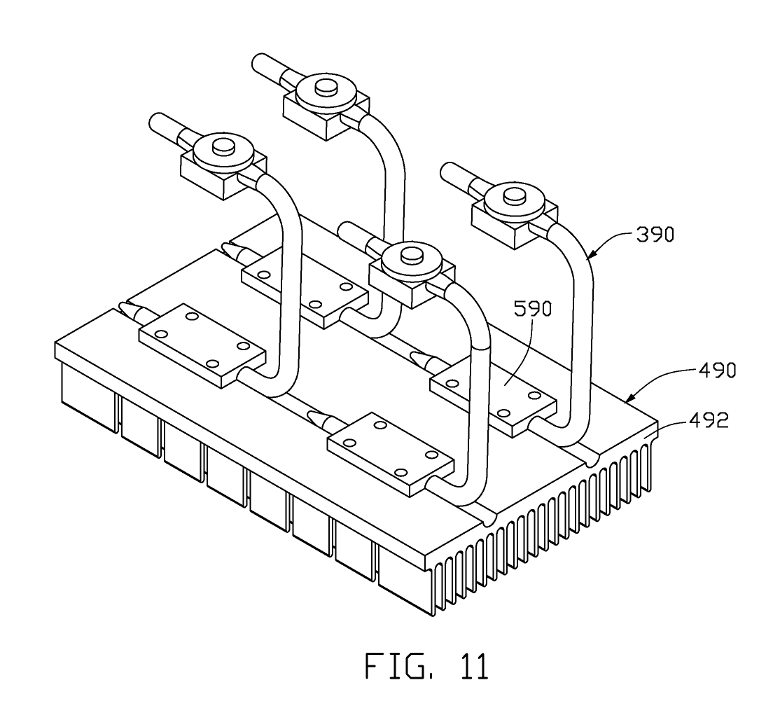

FIG. 11 is similar to FIG. 10. However, four metallic plates 590 are employed to engage with the base 492, in order to secure the heat pipes 390 to the base 492 of the heat-dissipating unit 490. The plates 200 can be made of aluminum or copper material.

It is believed that the present embodiments and their advantages will be understood from the foregoing description, and it will be apparent that various changes may be made thereto without departing from the spirit and scope of the invention or sacrificing all of its material advantages, the examples here described merely being preferred or exemplary embodiments of the invention.

What is claimed is:

1. An LED module comprising:
an LED;
a heat spreader contacting the LED;
a heat-dissipating unit being remote from the LED; and
a heat transfer member thermally connecting the heat spreader and the heat-dissipating unit, and transforming heat from the heat spreader to the heat-dissipating unit.

2. The LED module as claimed in claim 1, wherein the heat transfer member comprises a heat pipe having an evaporating section engaged in the heat spreader and a condensing section extending into the heat-dissipating unit.

3. The LED module as claimed in claim 2, wherein the heat-dissipating unit comprises a plurality of metallic fins transversely passing through the condensing section of the heat pipe.

4. The LED module as claimed in claim 2, wherein the heat pipe further comprises a connecting section connecting the evaporating section and the condensing section.

5. The LED module as claimed in claim 2, wherein the condensing section perpendicularly extends from an end of the evaporating section.

6. The LED module as claimed in claim 5, wherein the heat pipe has another condensing section extending from another end of the evaporating section.

7. The LED module as claimed in claim 6, wherein the another condensing section is inserted into the heat-dissipating unit.

8. The LED module as claimed in claim 6, further comprising another heat-dissipating unit having a plurality of fins transversely passing through the another condensing section of the heat pipe.

9. The LED module as claimed in claim 2, wherein the heat-dissipating unit comprises a base having a groove at a first side thereof and a plurality of fins at a second side thereof opposite to the first side, and wherein the condensing section of the heat pipe is received in the groove.

10. The LED module as claimed in claim 9, wherein a metallic plate is employed to secure the heat pipe into the groove of the base.

11. The LED module as claimed in claim 9, wherein all of the LED, the heat spreader and the heat pipe are located at the first side of the base, and all of the fins are located at the second side of the base.

12. The LED module as claimed in claim 1, wherein the heat spreader is provided with a plurality of metallic flakes thereon.

13. The LED module as claimed in claim 1, wherein the heat spreader is bared.
